(19) United States
(12) Patent Application Publication
(10) Pub. No.: US 2025/0369096 A1
(43) Pub. Date: Dec. 4, 2025

(54) FILM FORMATION PROCESSING SYSTEM AND METHOD OF CONTROLLING FILM FORMATION PROCESSING SYSTEM

(71) Applicant: Tokyo Electron Limited, Tokyo (JP)

(72) Inventor: Yusuke KIKUCHI, Tokyo (JP)

(21) Appl. No.: 19/220,188

(22) Filed: May 28, 2025

(30) Foreign Application Priority Data
Jun. 4, 2024 (JP) 2024-090764

(51) Int. Cl. C23C 14/54; H01L 21/67; H01L 21/677

(52) U.S. Cl. CPC C23C 14/541; H01L 21/67017; H01L 21/6719; H01L 21/67703

(57) ABSTRACT

A film formation processing system includes a first and a second film formation processing chambers configured to perform, respectively, a first and a second substrate processing on a substrate, a transfer chamber between the two film formation processing chambers, a temperature adjustment chamber in the transfer chamber configured to perform a temperature adjustment processing of the substrate on which the first substrate processing has been performed before the second substrate processing is performed, and a controller, wherein the temperature adjustment chamber includes a first processing container, a first stage inside the first processing container configured to place the substrate on the first stage, a first refrigerator configured to cool the first stage, a radiation shield between the first processing container and the first stage, and a first gas supply configured to supply a gas into the first processing container.

### CROSS-REFERENCE TO RELATED APPLICATIONS

This application is based upon and claims the benefit of priority from Japanese Patent Application No. 2024-090764, filed on Jun. 4, 2024, the entire contents of which are incorporated herein by reference.

### TECHNICAL FIELD

The present disclosure relates to a film formation processing system and a method of controlling the film formation processing system.

### BACKGROUND

Patent Document 1 discloses a method of cooling a substrate by bringing a cooler into direct contact with a stage on which the substrate is placed and processing the substrate while rotating the stage in a state in which the cooler is separated from the stage. The method includes cooling the cooler to a target temperature in a state in which the stage is brought into direct contact with the cooler and cooling the stage to an initial cooling temperature, increasing a temperature of the stage, controlling the temperature of the stage to a steady cooling temperature when the temperature of the stage reaches the steady cooling temperature, placing the substrate on the stage at the steady cooling temperature, and continuously performing a substrate processing on substrates while rotating the stage in a state in which the stage is separated from the cooler.

### PRIOR ART DOCUMENTS

### Patent Documents

Patent Document 1: Japanese Patent Laid-Open Publication No. 2023-116116

### SUMMARY

According to one embodiment of the present disclosure, there is provided a film formation processing system including a first film formation processing chamber configured to perform a first substrate processing on a substrate, a second film formation processing chamber configured to perform a second substrate processing on the substrate, a transfer chamber provided between the first and second film formation processing chambers, a temperature adjustment chamber provided in the transfer chamber and configured to perform a temperature adjustment processing of the substrate on which the first substrate processing has been performed before the second substrate processing is performed, and a controller, wherein the temperature adjustment chamber includes a first processing container, a first stage provided inside the first processing container to place the substrate on the first stage, a first refrigerator configured to cool the first stage, a radiation shield provided between the first processing container and the first stage, and a first gas supply configured to supply a gas into the first processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an example of a configuration diagram of a film formation processing system according to the present embodiment.

FIG. 2 is an example of a configuration diagram of a second film formation processing chamber during a cooling of a stage.

FIG. 3 is an example of a configuration diagram of the second film formation processing chamber during a film formation processing.

FIG. 4 is an example of a configuration diagram of a temperature adjustment chamber.

FIG. 5 is a flowchart illustrating an example of a substrate processing using the film formation processing system.

FIG. 6 is an example of a graph illustrating temperature variations of a stage and a cold link of the second film formation processing chamber upon transferring a substrate processed in a first film formation processing chamber to the second film formation processing chamber.

FIG. 7 is an example of a graph illustrating temperature variations of the stage and the cold link of the second film formation processing chamber upon transferring a substrate temperature-adjusted in the temperature adjustment chamber to the second film formation processing chamber.

FIG. 8 is an example of a graph illustrating temperature variations of a stage and a cold link of a temperature adjustment chamber upon transferring a substrate processed in the first film formation processing chamber to the temperature adjustment chamber.

FIG. 9 is an example of a graph illustrating temperature variations of the stage and the cold link of the second film formation processing chamber upon transferring the substrate temperature-adjusted in the temperature adjustment chamber to the second film formation processing chamber.

FIG. 10 is an example of a flowchart for explaining a pre-treatment in the first film formation processing chamber.

FIG. 11 is an example of a flowchart for explaining a pre-treatment in the second film formation processing chamber.

FIG. 12 is an example of a flowchart for explaining a pre-treatment in the temperature adjustment chamber.

FIG. 13 is an example of a graph illustrating a relationship between a pressure inside a processing container of the temperature adjustment chamber and a temperature variation of the stage of the temperature adjustment chamber.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings. Like reference numerals will be given to the substantially the same configurations throughout the drawings, and redundant descriptions thereof may be omitted.

### <Film Formation Processing System 1>

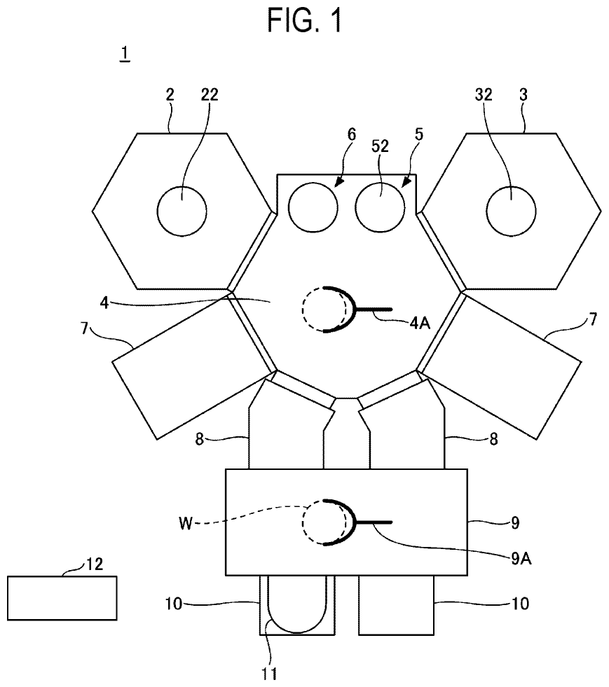

A film formation processing system 1 according to the present embodiment will now be described with reference to FIG. 1. FIG. 1 is an example of a configuration diagram of the film formation processing system 1 according to the present embodiment.

The film formation processing system 1 includes film formation processing chambers (processing modules) 2 and 3, a vacuum transfer chamber 4, a temperature adjustment chamber 5, a path module 6, a sub-module 7, a load lock chamber 8, an atmospheric transfer chamber 9, a load port 10, and a controller 12.

The first film formation processing chamber 2 is an apparatus that performs a first film formation processing for forming a first film on a substrate W at a first film formation temperature (a temperature higher than room temperature, for example, 300 degrees C.). The second film formation processing chamber 3 is an apparatus that performs a second film formation processing for forming a second film on the substrate W on which the first film has been formed, at a second film formation temperature (a temperature lower than room temperature or an extremely low temperature, for example, a temperature of 150 K or lower).

Here, the second film is, for example, a Cu film used as a wiring layer of a semiconductor device formed on the substrate W. The first film is a film used as a barrier layer for preventing Cu atoms of the second film from diffusing into the Si substrate. Specifically, the first film is a film of Ti, Ta, TiN, or TaN. The barrier performance of the Cu atoms by the barrier layer increases as a crystal grain size increases. Additionally, the crystal grain size increases as the film formation temperature increases. Therefore, in the first film formation processing chamber 2, the film formation processing is performed at a high temperature (e.g., 300 degrees C.). In contrast, in the second film formation processing chamber 3, the film formation processing is performed at an extremely low temperature (e.g., a temperature of 150 K or lower) to which the substrate W is cooled.

The first film formation processing chamber 2 is, for example, a physical vapor deposition (PVD) apparatus or a sputtering apparatus. The first film formation processing chamber 2 includes a stage 22 configured to place the substrate W on the stage 22. In addition, the first film formation processing chamber 2 includes a heater (not illustrated) configured to heat the stage 22 and the substrate W placed on the stage 22.

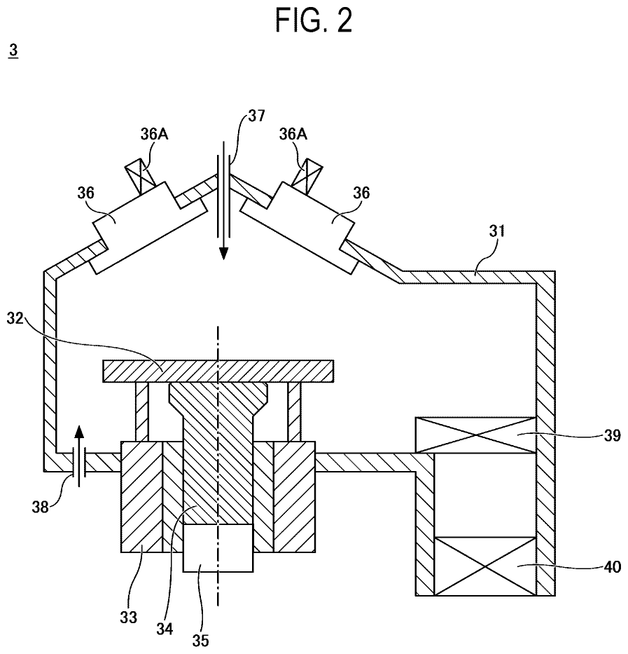

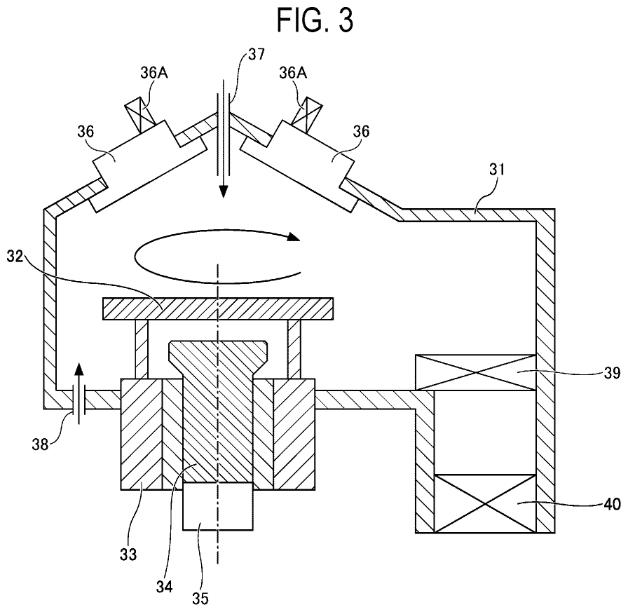

The second film formation processing chamber 3 is, for example, a PVD apparatus or a sputtering apparatus. The second film formation processing chamber 3 includes a stage 32 configured to place the substrate W on the stage 32. In addition, the second film formation processing chamber 3 includes a refrigerator 35 (see FIGS. 2 and 3 described later) configured to cool the stage 32 and the substrate W placed on the stage 32. Details of the second film formation processing chamber 3 will be described later with reference to FIGS. 2 and 3.

The vacuum transfer chamber 4 is maintained in a vacuum state and is connected to the film formation processing chambers 2 and 3, the path module 6, the sub-module 7, and the load lock chamber 8 via gate valves. The vacuum transfer chamber 4 is provided with a transfer device 4A configured to transfer the substrate W.

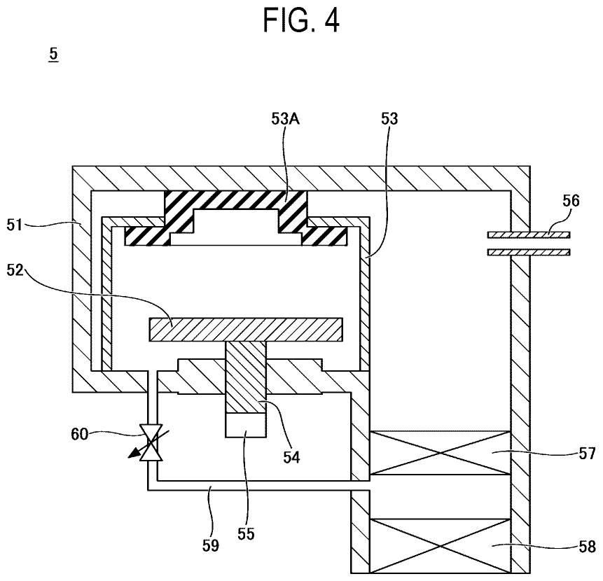

The vacuum transfer chamber 4, which serves as a transfer path from the first film formation processing chamber 2 to the second film formation processing chamber 3, is provided with the temperature adjustment chamber 5. The temperature adjustment chamber 5 includes a stage 52 configured to place the substrate W on the stage 52. Furthermore, the temperature adjustment chamber 5 includes a refrigerator (not illustrated) configured to cool the stage 52 and the substrate W placed on the stage 52. The high-temperature substrate W on which the first film has been formed in the first film formation processing chamber 2 is transferred and then cooled in the temperature adjustment chamber 5. Details of the temperature adjustment chamber 5 will be described later with reference to FIG. 4.

The path module 6 is a module used when the substrate W is transferred to another vacuum transfer chamber (not illustrated) adjacent to the vacuum transfer chamber 4.

The sub-module 7 performs a pre-treatment on the substrate W before a processing is performed in the first film formation processing chamber 2. The pre-treatment performed on the substrate W in the sub-module 7 may include any of degassing treatment, pre-cleaning treatment, etc.

The load lock chamber 8 is hermetically connected to the vacuum transfer chamber 4 and switches an internal atmosphere of the load lock chamber 8 between a vacuum atmosphere and the air atmosphere. In the present embodiment, two load lock chambers 8 are provided but the number of load lock chambers is not limited to two.

A common atmospheric transfer chamber 9 configured to transfer the substrate W under the air atmosphere is connected to the two load lock chambers 8. The atmospheric transfer chamber 9 is provided with the load port 10 for loading a carrier 11. The atmospheric transfer chamber 9 is provided with a transfer device 9A configured to transfer the substrate W between the load lock chambers 8 and the carrier 11 of the load port 10. The substrate W is accommodated in the carrier 11.

The film formation processing system 1 configured as described above includes the controller 12 which is composed of, for example, a computer. The controller 12 controls the overall operation of the film formation processing system 1. The controller 12 includes a memory and a central processing unit (CPU). The memory stores programs and recipes used for performing the film formation processing in the film formation processing chambers 2 and 3. The programs include a program related to input manipulations or displays of processing parameters. Process conditions or processing orders of the film formation processing chambers 2 and 3, and a transfer route of the substrate W are set in the recipes.

The CPU transfers the substrate W taken out of the carrier 11 to the first film formation processing chamber 2, the temperature adjustment chamber 5, and the second film formation processing chamber 3 along a predetermined path using the transfer device 9A of the atmospheric transfer chamber 9 and the transfer device 4A of the vacuum transfer chamber 4, according to the programs and recipes stored in the memory. The CPU performs a predetermined film formation processing in the film formation processing chambers 2 and 3 based on the process conditions set in the recipes. The programs may be stored in a computer storage medium, for example, the memory such as a flexible disk, a compact disc, a hard disk, or a magneto-optical (MO) disc and installed in the controller 12 or may be downloaded using a communication function.

### <First Film Formation Processing Chamber 2>

The first film formation processing chamber 2 is, for example, a PVD apparatus. The first film formation processing chamber 2 is not limited thereto and may also be a thermal chemical vapor deposition (CVD) apparatus, a plasma-enhanced CVD (PECVD) apparatus, or any other type of film formation apparatus.

### <Second Film Formation Processing Chamber 3>

Next, the second film formation processing chamber 3 will be described with reference to FIGS. 2 and 3. FIG. 2 is an example of a configuration diagram of the second film formation processing chamber 3 during a cooling of the stage 32. FIG. 3 is an example of a configuration diagram of the second film formation processing chamber 3 during a film formation processing.

The second film formation processing chamber 3 is a PVD sputtering apparatus (film formation apparatus). The second film formation processing chamber 3 includes a processing container 31, the stage 32, a stage rotation mechanism 33, a cold link 34, a refrigerator 35, a target 36, gas supplies 37 and 38, an exhaust valve 39, and a turbomolecular pump 40.

The processing container 31 is connected to the vacuum transfer chamber 4 (see FIG. 1) via a gate valve.

The stage 32 includes a placement surface on which the substrate W is placed. Additionally, the stage 32 is provided with an electrostatic chuck (not illustrated) configured to electrostatically adsorb the substrate W. The second film formation processing chamber 3 includes a heat transfer gas supply (not illustrated) that supplies heat transfer gas (e.g., He gas) to a space between a rear surface of the adsorbed substrate W and a surface (placement surface) of the stage 32.

The stage rotation mechanism 33 rotates the stage 32 around a central axis of the stage 32 (indicated by a dash-dotted line) as a rotation axis when the cold link 34 is separated from the stage 32 (see FIG. 3). This enhances in-plane uniformity when a film is formed on the substrate W.

The refrigerator 35 holds the cold link 34 and cools an upper surface of the cold link 34 to an extremely low temperature. From the perspective of cooling capacity, it is desirable for the refrigerator 35 to use a Gifford-McMahon (GM) cycle. The cold link 34 is fixed to the refrigerator 35, and an upper portion of the cold link 34 is accommodated inside the processing container 31. The cold link 34 is made of a material (e.g., Cu) having a high thermal conductivity and is formed in a substantially cylindrical shape. The cold link 34 is disposed so that a center of the cold link 34 coincides with the central axis of the stage 32.

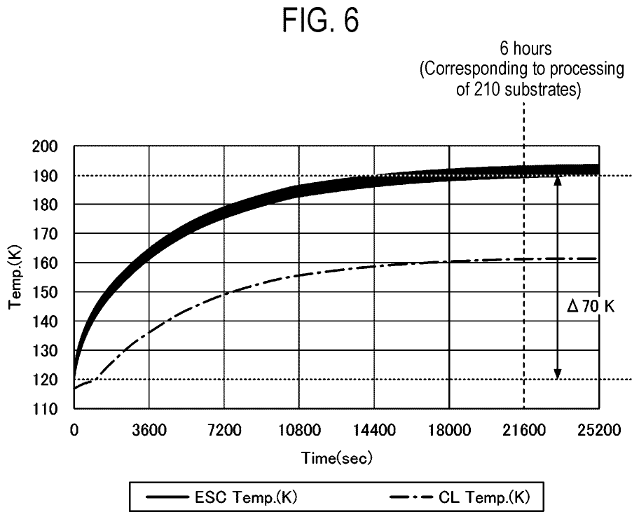

Additionally, the refrigerator 35 controls refrigeration capacity based on a temperature detected by a temperature sensor (not illustrated) provided in the cold link 34. That is, the refrigerator 35 controls the refrigeration capacity so that a value detected by the temperature sensor provided in the cold link 34 becomes a predetermined temperature (117 K in the examples of FIGS. 6, 7, and 9).

The second film formation processing chamber 3 further includes a lifting mechanism (not illustrated) that raises and lowers the cold link 34 and the refrigerator 35. By raising the cold link 34 and the refrigerator 35 using the lifting mechanism, the upper surface of the cold link 34 comes into contact with a lower surface of the stage 32, as illustrated in FIG. 2, which cools the stage 32. Further, by lowering the cold link 34 and the refrigerator 35 using the lifting mechanism, the upper surface of the cold link 34 is separated from the lower surface of the stage 32, as illustrated in FIG. 3, which enables the rotation of the stage 32.

On a ceiling (lid) of the processing container 31, the target 36 serving as a sputtering source and the gas supply 37 that supplies a sputtering gas (Ar gas) are disposed. A voltage is applied to a target holder that holds the target 36. As a result, the surface of the target 36 is sputtered by the sputtering gas, and the sputtered particles (film formation atoms) emitted from the surface of the target 36 are attached to (deposited on) the surface of the substrate W placed on the stage 32. As a result, film formation processing is performed on the substrate W. An oscillating magnet 36A may be provided on a rear surface of the target 36.

Moreover, a bottom surface portion of the processing container 31 may be provided with the gas supply 38 that supplies a gas (e.g., N₂ gas). This N₂ gas can be used, for example, during a reactive sputtering.

The lower portion of the processing container 31 is also provided with the exhaust valve 39 and the turbomolecular pump 40 to depressurize an interior of the processing container 31 to a predetermined vacuum atmosphere.

With the above configuration, the second film formation processing chamber 3 cools the stage 32 and the substrate W placed on the stage 32 by bringing the stage 32 into contact with the cold link 34, as illustrated in FIG. 2. Furthermore, as illustrated in FIG. 3, the second film formation processing chamber 3 separates the stage 32 from the cold link 34 and sputters the target 36 while rotating the stage 32. This enables film formation processing on the substrate W at an extremely low temperature.

### <Temperature Adjustment Chamber 5>

Next, the temperature adjustment chamber 5, which is provided in the vacuum transfer chamber 4, will be described with reference to FIG. 4. FIG. 4 is an example of a configuration diagram of the temperature adjustment chamber 5.

The temperature adjustment chamber 5 includes a processing container 51, a stage 52, a radiation shield 53, a cold link 54, a refrigerator 55, a gas supply 56, an exhaust valve 57, a turbomolecular pump 58, a bypass line 59, and a pressure regulating valve 60.

The processing container 51 is provided inside the vacuum transfer chamber 4. The processing container 51 is connected to the vacuum transfer chamber 4 (see FIG. 1) via a gate valve (not illustrated). That is, by opening the gate valve, an internal space of the vacuum transfer chamber 4 and an internal space of the processing container 51 of the temperature adjustment chamber 5 communicate with each other. Further, by closing the gate valve, the internal space of the processing container 51 of the temperature adjustment chamber 5 can be isolated from the internal space of the vacuum transfer chamber 4. As a result, when the gate valve is closed, a pressure inside the processing container 51 of the temperature adjustment chamber 5 can be maintained higher than a pressure inside the vacuum transfer chamber 4.

The stage 52 has a placement surface on which the substrate W is placed. Additionally, the stage 52 is provided with an electrostatic chuck (not illustrated) that electrostatically adsorbs the substrate W. The temperature adjustment chamber 5 includes a heat transfer gas supply (not illustrated) that supplies a heat transfer gas (e.g., He gas) to a space between the rear surface of the adsorbed substrate W and the placement surface of the stage 52.

On a ceiling (lid) of the processing container 51, the radiation shield 53 is suspended via an adapter 53A. The adapter 53A is made of a material having a low thermal conductivity (e.g., ceramic) to suppress heat transfer between the processing container 51 and the radiation shield 53. The radiation shield 53 shields the stage 52 from the heat radiated from the ceiling and the sidewalls of the processing container 51. Additionally, the radiation shield 53 is provided with an opening (not illustrated) for transferring the substrate W. An inner space of the radiation shield 53 and an outer space of the radiation shield 53 communicate with each other.

The refrigerator 55 holds the cold link 54 and cools the upper surface of the cold link 54 to an extremely low temperature. From the perspective of cooling capacity, it is desirable for the refrigerator 35 to use a Gifford-McMahon (GM) cycle. The cold link 54 is fixed to the refrigerator 55, and the upper portion of the cold link 54 is accommodated inside the processing container 51. The cold link 54 is made of a material (e.g., Cu) having a high thermal conductivity and is formed in a substantially cylindrical shape. The cold link 54 is disposed so that a center of the cold link 54 coincides with a central axis of the stage 52.

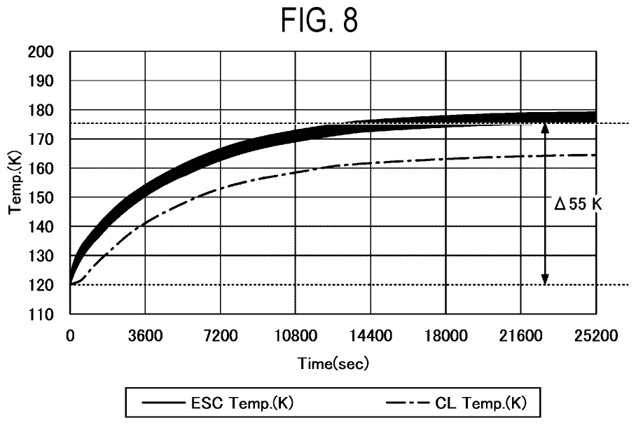

Additionally, the refrigerator 55 controls refrigeration capacity based on a temperature detected by a temperature sensor (not illustrated) provided in the cold link 54. That is, the refrigerator 55 controls the refrigeration capacity so that a value detected by the temperature sensor provided in the cold link 54 becomes a predetermined temperature (120 K in the example of FIG. 8).

A sidewall of the processing container 51 is provided with the gas supply 56 that supplies a gas (e.g., Ar gas) into the processing container 51. The gas supplied by the gas supply 56 is a noble gas (e.g., Ar gas). The gas supplied by the gas supply 56 is not limited thereto and may also be a noble gas such as He gas or Kr gas or an inert gas such as N₂ gas. The gas supplied into the processing container 51 by the gas supply 56 is used to heat the stage 52 through thermal convection. Furthermore, the gas supplied into the processing container 51 by the gas supply 56 is of a higher temperature (e.g., room temperature) than the temperature of the stage 52 which is cooled to an extremely low temperature.

A bottom surface portion of the processing container 51 is provided with the exhaust valve 57 and the turbomolecular pump 58 to depressurize an interior of the processing container 51 to a predetermined vacuum atmosphere.

The bypass line 59 has one end connected to the interior of the processing container 51, specifically, to a space inside the radiation shield 53 and the other end connected between the exhaust valve 57 and the turbomolecular pump 58. In addition, the pressure regulating valve 60 is provided in the bypass line 59. Accordingly, even when the exhaust valve 57 is closed, the interior of the processing container 51 may be exhausted to the turbomolecular pump 58 via the bypass line 59, and an internal pressure of the processing container 51 can be regulated by the pressure regulating valve 60.

With the above configuration, the temperature adjustment chamber 5 can cool the stage 52 and the substrate W placed on the stage 52.

Additionally, by closing the gate valve of the processing container 51 of the temperature adjustment chamber 5, closing the exhaust valve 57 of the temperature adjustment chamber 5, and supplying a gas into the processing container 51 by the gas supply 56, the pressure inside the processing container 51 of the temperature adjustment chamber 5 can be made higher than the pressure of an internal space of the vacuum transfer chamber 4. In this case, the pressure inside the processing container 51 can be adjusted by the pressure regulating valve 60 provided in the bypass line 59.

### <Film Formation Processing>

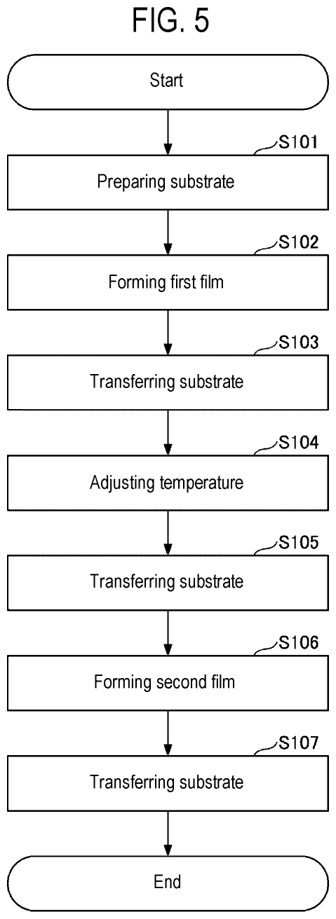

Next, an example of a substrate processing using the film formation processing system 1 will be described with reference to FIG. 5. FIG. 5 is a flowchart illustrating an example of the substrate processing using the film formation processing system 1.

In step S101, the substrate W is prepared. Here, the controller 12 controls the transfer device 9A to take the substrate W out of the carrier 11 and transfer the substrate W to the load lock chamber 8. Subsequently, the controller 12 controls the transfer device 4A to take the substrate W out of the load lock chamber 8 and transfer the substrate W to the first film formation processing chamber 2. Additionally, before the substrate W is transferred to the first film formation processing chamber 2, the substrate W may be transferred to the sub-module 7 in which a pre-treatment (degassing, pre-cleaning processing, etc.) may be performed.

In step S102, a first film is formed on the substrate W. Here, the controller 12 controls the first film formation processing chamber 2 to heat the substrate W to a first film formation temperature (e.g., 300 degrees C.) and then perform the first film formation processing on the substrate W, which forms the first film on the substrate W. That is, after the first film formation processing, the substrate W is at the first film formation temperature.

In step S103, the substrate W is transferred. Here, the controller 12 controls the transfer device 4A to take the substrate W out of the first film formation processing chamber 2 and transfer the substrate W to the temperature adjustment chamber 5.

In step S104, the temperature of the substrate W is adjusted. Here, the controller 12 controls the temperature adjustment chamber 5 to cool the substrate W to a predetermined cooling temperature (an extremely low temperature, for example, a temperature of 150 K or lower).

In step S105, the substrate W is transferred. Here, the controller 12 controls the transfer device 4A to take the substrate W out of the temperature adjustment chamber 5 and transfer the substrate W to the second film formation processing chamber 3.

In step S106, a second film is formed on the substrate W. Here, the controller 12 controls the second film formation processing chamber 3 to cool the substrate W to a second film formation temperature (an extremely low temperature, for example, a temperature of 150 K or lower) and then perform the second film formation processing, which forms the second film on the substrate W.

In step S107, the substrate W is transferred. Here, the controller 12 controls the transfer device 4A to take the substrate W out of the second film formation processing chamber 3 and transfer the substrate W to the load lock chamber 8. Then, the controller 12 controls the transfer device 9A to take the substrate W out of the load lock chamber 8 and accommodate the substrate W in the load port 10.

### <Temperature Variation of Stage During Continuous Processing>

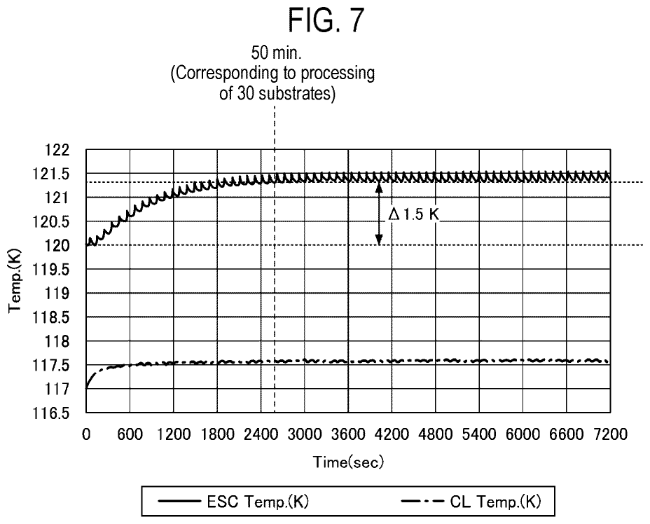

Next, a temperature variation of the stage 32 in the second film formation processing chamber 3 while the substrate W is continuously processed in the film formation processing system 1 will be described with reference to FIGS. 6 and 7.

FIG. 6 is an example of a graph illustrating temperature variations of the stage 32 and the cold link 34 of the second film formation processing chamber 3 upon transferring the substrate W processed in the first film formation processing chamber 2 to the second film formation processing chamber 3. In FIG. 6, the horizontal axis represents time, and the vertical axis represents temperature. Additionally, the temperature (ESC Temp) of the stage 32 is represented by a solid line, and the temperature of the cold link 34 (CL Temp) is represented by a dash-dotted line. In the example of FIG. 6, the substrate W at a temperature of 300 degrees C. is transferred to the second film formation processing chamber 3. Furthermore, an output of the refrigerator 35 is controlled so that the temperature of the cold link 34 reaches a predetermined temperature (117 K in this case).

As the high-temperature substrate W is placed on the stage 32, the temperature of the stage 32 increases. Additionally, in the second film formation processing, the heat generated by sputtering during the film formation processing is transferred to the stage 32 via the substrate W, which increases the temperature of the stage 32. Moreover, as a room-temperature process gas supplied during the film formation processing is supplied into the processing container 31, the temperature of the stage 32 increases.

After the second film formation processing (see FIG. 3), the cold link 34 is brought into contact with the stage 32 to cool the stage 32 (see FIG. 2), which increases the temperature of the cold link 34 and cooling the stage 32.

Here, the film formation processing system 1 continuously processes the substrate W with high throughput. In other words, the processing of the next substrate W is started before the stage 32 and the cold link 34 are cooled to an original temperature (120K and 117 K, respectively, in this case). Consequently, heat is accumulated in the stage 32 and the temperature of the stage 32 gradually increases. In the example of FIG. 6, after approximately six hours (corresponding to processing of 210 substrates W), the stage 32 reaches thermal equilibrium at 190 K, which is about 70 K higher than the original temperature, and the temperature of the stage 32 is saturated and stabilized.

FIG. 7 is an example of a graph illustrating temperature variations of the stage 32 and the cold link 34 of the second film formation processing chamber 3 upon transferring the substrate W temperature-adjusted in the temperature adjustment chamber 5 to the second film formation processing chamber 3. In FIG. 7, the horizontal axis represents time, and the vertical axis represents temperature. The temperature (ESC Temp) of the stage 32 is illustrated by a solid line, and the temperature (CL Temp) of the cold link 34 is represented by a dash-dotted line. In the example of FIG. 7, the substrate W cooled to 120 K in the temperature adjustment chamber 5 is transferred to the second film formation processing chamber 3. Additionally, the output of the refrigerator 35 is controlled so that the temperature of the cold link 34 reaches a predetermined temperature (117 K in this case).

As the processing of the substrate W is repeated, the temperature of the stage 32 and the cold link 34 gradually increases. In the example of FIG. 7, after approximately 50 minutes (corresponding to processing 30 substrates W), the stage 32 reaches thermal equilibrium at 121.5 K, which is about 1.5 K higher than the original temperature, and the temperature of the stage 32 is saturated and stabilized.

By using the temperature adjustment chamber 5 as described above, a temperature drift of the stage 32 (a temperature difference from an initial temperature of 120 K of the stage 32 to a saturation temperature at which the stage 32 reaches thermal equilibrium) can be reduced. Additionally, the time required for the stage 32 to reach thermal equilibrium can be shortened.

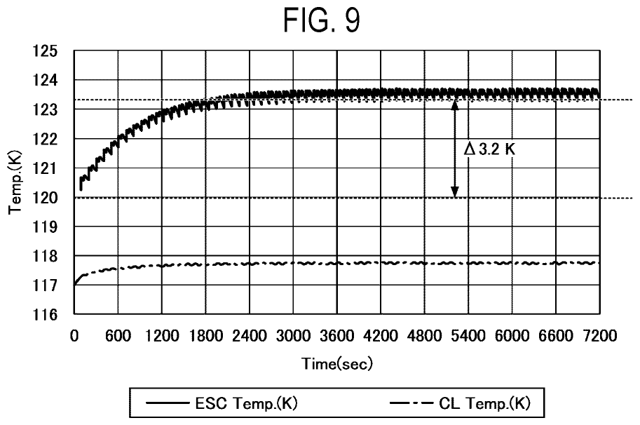

Next, a temperature variation of the stage 52 of the temperature adjustment chamber 5 and a temperature variation of the stage 32 of the second film formation processing chamber 3 upon continuously processing the substrates W in the film formation processing system 1 will be described with reference to FIGS. 8 and 9.

FIG. 8 is an example of a graph illustrating temperature variations of the stage 52 and the cold link 54 of the temperature adjustment chamber 5 upon transferring the substrate W processed in the first film formation processing chamber 2 to the temperature adjustment chamber 5. In FIG. 8, the horizontal axis represents time, and the vertical axis represents temperature. The temperature (ESC Temp) of the stage 52 is represented by a solid line, and the temperature (CL Temp) of the cold link 54, which cools the stage 52, is represented by a dash-dotted line. In the example of FIG. 8, the substrate W of 300 degrees C. is transferred to the temperature adjustment chamber 5. Additionally, an output of the refrigerator 55 is controlled so that the temperature of the cold link 54 reaches a predetermined value (120 K in this case).

As the high-temperature substrate W is placed on the stage 52, the substrate W is cooled and the temperature of the stage 52 increases. Additionally, as the substrate W is unloaded from the stage 52, the temperature of the stage 52 decreases. Before the stage 52 and the cold link 54 are cooled to an original temperature (120 K in this case), the next substrate W is placed. Consequently, heat is accumulated in the stage 52 and the temperature of the stage 52 gradually increases. In the example illustrated in FIG. 8, the stage 52 reaches thermal equilibrium at 175 K, which is about 55 K higher than the original temperature, and the temperature of the stage 52 is saturated and stabilized.

FIG. 9 is an example of a graph illustrating temperature variations of the stage 32 and the cold link 34 of the second film formation processing chamber 3 upon transferring the substrate temperature-adjusted in the temperature adjustment chamber 5 to the second film formation processing chamber 3. In FIG. 9, the horizontal axis represents time, and the vertical axis represents temperature. The temperature (ESC Temp) of the stage 32 is represented by a solid line, and the temperature (CL Temp) of the cold link 34 is represented by a dash-dotted line. In the example of FIG. 9, following the example of FIG. 8, the substrate W of 175 K is transferred to the second film formation processing chamber 3. Additionally, the output of the refrigerator 35 is controlled so that the temperature of the cold link 34 reaches a predetermined value (117 K in this case).

As the substrate W is repeated processed repeatedly, the temperature of the stage 32 gradually increases. In the example of FIG. 9, the stage 32 reaches thermal equilibrium at 123.2 K, which is about 3.2 K higher than the original temperature, and the temperature of the stage 32 is saturated and stabilized.

By cooling (e.g., to 175 K), in the temperature adjustment chamber 5, the high-temperature substrate W (e.g., 300 degrees C.) processed in the first film formation processing chamber 2 illustrated in FIGS. 8 and 9 and then processing the substrate W in the second film formation processing chamber 3, the increase in the temperature of the stage 32 during the continuous processing of the substrate W can be significantly suppressed compared to the case in which the high-temperature substrate W (e.g., 300 degrees C.) processed in the first film formation processing chamber 2 is directly processed in the second film formation processing chamber 3 as illustrated in FIG. 6.

As illustrated in FIG. 8, the temperature of the stage 52 of the temperature adjustment chamber 5 varies by about 55 K due to the continuous processing of the substrate W. As illustrated in FIG. 9, the temperature of the stage 32 of the second film formation processing chamber 3 varies by about 3.2 K due to the continuous processing of the substrate W. If the temperature of the substrate W in the second film formation processing chamber 3 at a starting time of film formation differs for each substrate W, this may affect the quality of the second film formed.

For this reason, a pre-treatment is performed before starting the continuous film formation processing on the substrate W. In the pre-treatment, the temperature of the stage 52 of the temperature adjustment chamber 5 is increased in advance to a saturation temperature (175 K in the example of FIG. 8) at which the stage 52 reaches thermal equilibrium, and the temperature of the stage 32 of the second film formation processing chamber 3 is increased in advance to a saturation temperature (123.2 K in the example of FIG. 9) at which the stage 32 reaches thermal equilibrium.

As a result, the film formation processing system 1 enables a film formation processing with high throughput and stabilizes a temperature at the starting time of the film formation, which can suppress variations in the quality of the second film formed on each substrate W.

### <Pre-Treatment>

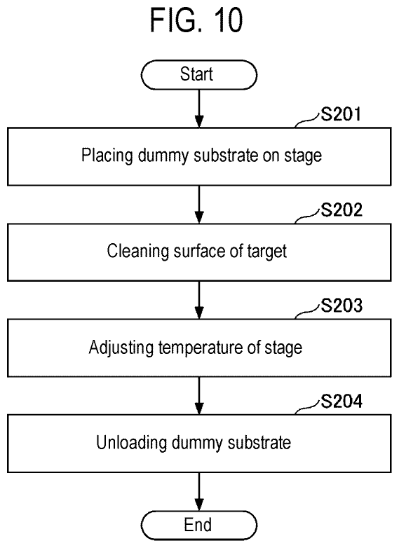

A pre-treatment of the film formation processing system 1 will now be described with reference to FIGS. 10 to 12. The pre-treatment is a treatment performed before starting the substrate processing (film formation processing) illustrated in FIG. 5. After the pre-treatment (refer to FIGS. 10 to 12) is performed, the substrate processing (film formation processing) illustrated in FIG. 5 is continuously performed. In the pre-treatment, the temperatures of the stages 22, 32, and 52 are adjusted to the saturation temperatures at which the respective stages reach thermal equilibriums.

FIG. 10 is an example of a flowchart for explaining a pre-treatment in the first film formation processing chamber 2. Here, a description is given based on a PVD apparatus as the first film formation processing chamber 2.

In step S201, a dummy substrate is placed on the stage 22. Here, the controller 12 controls the transfer device 4A to place the dummy substrate on the stage 22.

In step S202, the surface of a target is cleaned. Here, a surface of the target is sputtered by supplying a sputtering gas into the processing container and applying a voltage to a target holder that holds the target. As a result, the surface of the target is cleaned.

In step S203, the temperature of the stage 22 is adjusted. Here, the stage 22 is heated to a predetermined temperature using the heater provided in the stage 22.

In step S204, the dummy substrate is unloaded from the stage 22. Here, the controller 12 controls the transfer device 4A to unload the dummy substrate from the stage 22.

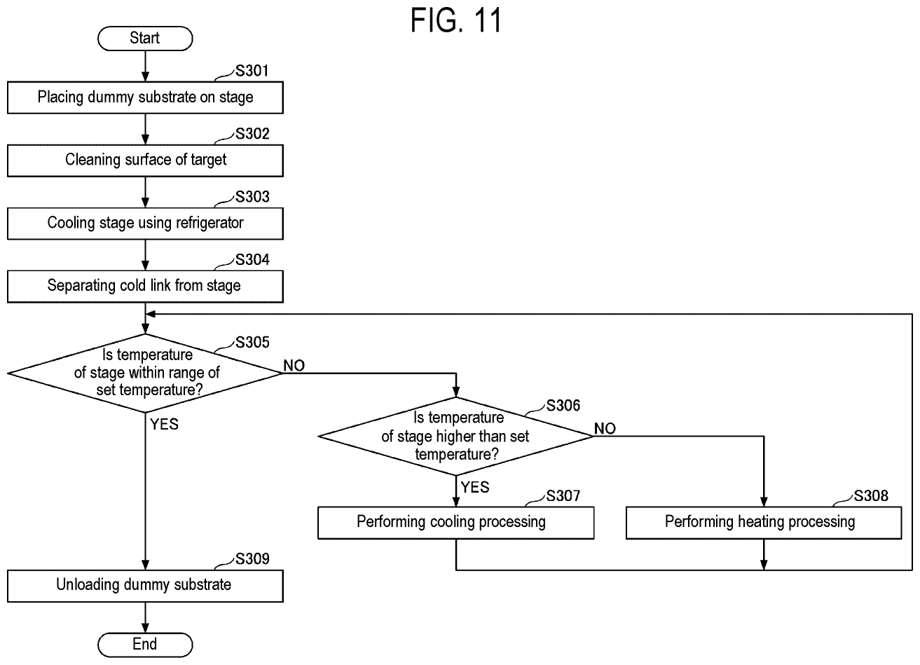

FIG. 11 is an example of a flowchart for explaining a pre-treatment in the second film formation processing chamber 3 (refer to FIGS. 2 and 3).

In step S301, a dummy substrate is placed on the stage 32. Here, the controller 12 controls the transfer device 4A to place the dummy substrate on the stage 32.

In step S302, the surface of the target 36 is cleaned. Here, the controller 12 controls the gas supply 37 to supply a sputtering gas into the processing container 31 and apply a voltage to the target holder that holds the target 36, sputtering the surface of the target 36 as a result. As a result, the surface of the target 36 is cleaned.

In step S303, the stage 32 is cooled by the refrigerator 35. Here, the controller 12 controls the lifting mechanism (not illustrated) to raise the cold link 34 and the refrigerator 35, which brings the stage 32 into contact with the cold link 34 (refer to FIG. 2). Then, the stage 32 is cooled using the refrigerator 35. As a result, the stage 32 and the cold link 34 are cooled to a predetermined temperature (117 K in the example illustrated in FIG. 9).

In step S304, the cold link 34 is separated from the stage 32. Here, the controller 12 controls the lifting mechanism (not illustrated) to lower the cold link 34 and the refrigerator 35, which separates the cold link 34 from the stage 32 (refer to FIG. 3). As a result, the temperature of the stage 32 increases by the heat radiated from the processing container 31 or the like. When cleaning the target 36, the heat generated by sputtered particles incident on the dummy substrate is transferred to the stage 32, which increases the temperature of the stage 32. As the sputtering gas of room temperature supplied during the cleaning is supplied into the processing container 31, the temperature of the stage 32 increases.

Although a description has been given based on the case in which the target 36 is sputtered while the temperature of the stage 32 increases, the embodiment is not limited to such a case and the target 36 does not necessarily need to be sputtered. The temperature of the stage 32 may increase by supplying a gas into the processing container 31 to transfer the heat of the processing container 31 to the stage 32 through gas convection.

In step S305, whether the temperature of the stage 32 is within a range of a predetermined set temperature is determined. Here, the range of the predetermined set temperature is a range including the saturation temperature (123.2 K in the example of FIG. 9) at which the stage 32 reaches the thermal equilibrium (e.g., a range of +1 K from the saturation temperature, i.e., a range of 122.2 K to 124.2 K). The controller 12 detects the temperature of the stage 32 using the temperature sensor (not illustrated) provided in the stage 32. The controller 12 then determines whether the detected temperature of the stage 32 is within the range of the predetermined set temperature.

If the temperature of the stage 32 is not within the range of the predetermined set temperature (S305, NO), the procedure of the controller 12 proceeds to step S306.

In step S306, whether the temperature of the stage 32 is higher than the predetermined set temperature is determined.

If the temperature of the stage 32 is higher than the predetermined set temperature (S306, YES), the procedure of the controller 12 proceeds to step S307. In step S307, a cooling processing is performed on the stage 32. Here, the controller 12 controls the lifting mechanism (not illustrated) to raise the cold link 34 and the refrigerator 35, which brings the cold link 34 into contact with the stage 32. As a result, the stage 32 is cooled. The procedure of the controller 12 then returns to step S305.

If the temperature of the stage 32 is lower than the predetermined set temperature (S306, NO), the procedure of the controller 12 proceeds to step S308. In step S308, a heating processing is performed on the stage 32. Here, the controller 12 controls the lifting mechanism (not illustrated) to lower the cold link 34 and the refrigerator 35, which separates the cold link 34 from the stage 32. As a result, the temperature of the stage 32 increases by the heat radiated from the processing container 31, the heat of the sputtered particles, the heat of the sputtering gas, etc. The procedure of the controller 12 then returns to step S305.

If the temperature of the stage 32 is within the range of the predetermined set temperature (S305, YES), the procedure of the controller 12 proceeds to step S309.

In step S309, the dummy substrate is unloaded from the stage 32. Here, the controller 12 controls the transfer device 4A to unload the dummy substrate from the stage 32.

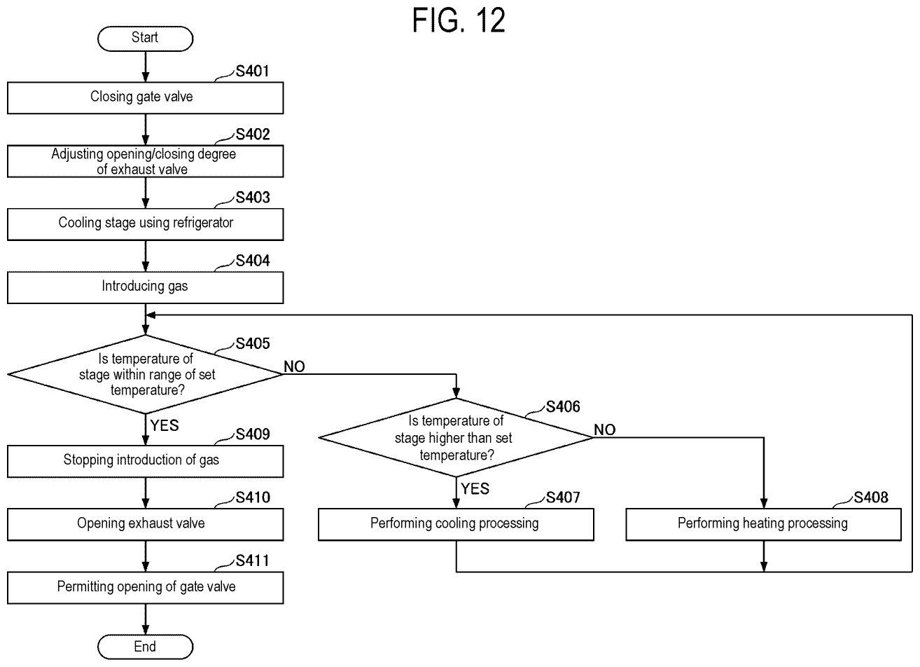

FIG. 12 is an example of a flowchart for explaining a pre-treatment in the temperature adjustment chamber 5 (see FIG. 4).

In step S401, a gate valve is closed. Here, the processing container 51 of the temperature adjustment chamber 5 is provided inside the vacuum transfer chamber 4, and a gate valve enabling the transfer of the substrate W is provided on a sidewall that partitions the vacuum transfer chamber 4 from the temperature adjustment chamber 5. In step S401, the gate valve is closed to isolate the internal space of the processing container 51 of the temperature adjustment chamber 5 from the internal space of the vacuum transfer chamber 4.

In step S402, an opening and closing degree of the exhaust valve 57 is adjusted. Here, the controller 12 adjusts the opening and closing degree of the exhaust valve 57 to a small degree or completely closes the exhaust valve 57. In addition, the controller 12 adjusts an opening and closing degree of the pressure regulating valve 60 of the bypass line 59.

In step S403, the stage 52 is cooled by the refrigerator 55. As a result, the stage 52 and the cold link 54 are cooled to a predetermined temperature (120 K in the example of FIG. 8).

In step S404, a gas is introduced into the processing container 51. Here, the controller 12 controls the gas supply 56 to introduce a room-temperature gas. As a result, the processing container 51 is filled with the gas to the pressure set in step S402. This gas transfers heat through convection between a wall surface of the processing container 51 and the stage 52. In addition, the heat of the room-temperature gas is transferred to the stage 52, which increases the temperature of the stage 52.

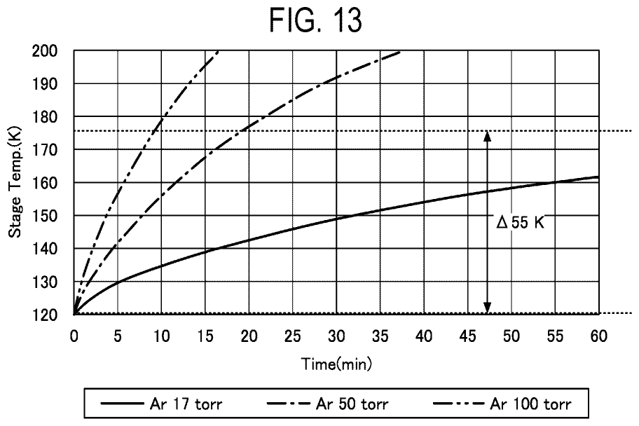

Here, the temperature variation of the stage 52 due to the gas will now be described with reference to FIG. 13. FIG. 13 is an example of a graph illustrating the relationship between the pressure inside the processing container 51 of the temperature adjustment chamber 5 and the temperature variation of the stage 52 of the temperature adjustment chamber 5. The graph represents the temperature variation of the stage 52 when an argon (Ar) gas is introduced. The case of 100 Torr is represented by a solid line, the case of 50 Torr is represented by a dash-single dotted line, and the case of 17 Torr is represented by a dash double-dotted line.

As illustrated in FIG. 13, the introduction of a gas can shorten the time required to increase the temperature of the stage 52 to the saturation temperature (A 55 K) at which the stage 52 reaches the thermal equilibrium.

Referring back to FIG. 12, in step S405, whether the temperature of the stage 52 is within a range of a predetermined set temperature is determined. Here, the range of the predetermined set temperature is a range including the saturation temperature (175 K in the example of FIG. 8) at which the stage 52 reaches the thermal equilibrium (e.g., a range of ±1 K from the saturation temperature, i.e., a range of 174 K to 176 K). The controller 12 detects the temperature of the stage 52 using the temperature sensor (not illustrated) provided in the stage 52. The controller 12 then determines whether the detected temperature of the stage 52 is within the range of the predetermined set temperature.

If the temperature of the stage 52 is not within the range of the predetermined set temperature (S405, NO), the procedure of the controller 12 proceeds to step S406.

In step S406, whether the temperature of the stage 52 is higher than the predetermined set temperature is determined.

If the temperature of the stage 52 is higher than the predetermined set temperature (S406, YES), the procedure of the controller 12 proceeds to step S407. In step S407, a cooling processing is performed on the stage 52. Here, the controller 12 controls the gas supply 56 to reduce the flow rate of the introduced gas and/or controls the pressure regulating valve 60 to lower the pressure inside the processing container 51, which reduces the heat input to the stage 52 and cools the stage 52 using the refrigerator 55. The procedure of the controller 12 then returns to step S405.

If the temperature of the stage 52 is lower than the predetermined set temperature (S406, NO), the procedure of the controller 12 proceeds to step S408. In step S408, heating processing is performed on the stage 52. Here, the controller 12 controls the gas supply 56 to increase the flow rate of the introduced gas and/or controls the pressure regulating valve 60 to increase the pressure inside the processing container 51, which promotes increases of the temperature of the stage 52. The procedure of the controller 12 then returns to step S405.

If the temperature of the stage 52 is within the range of the predetermined set temperature (S405, YES), the procedure of the controller 12 proceeds to step S409.

In step S409, the introduction of the gas is stopped. Here, the controller 12 controls the gas supply 56 to stop the introduction of the gas.

In step S410, the exhaust valve 57 is opened. As a result, the inside of the processing container 51 is depressurized to the same pressure level as the vacuum transfer chamber 4 by the turbomolecular pump 58.

In step S411, the opening of the gate valve is permitted.

The pre-treatment illustrated in FIGS. 10 to 12 may be performed simultaneously in parallel or may be implemented sequentially. If the pre-treatments of the first film formation processing chamber 2, the second film formation processing chamber 3, and the temperature adjustment chamber 5 are completed, the film formation processing of the substrate W (see FIG. 5) is continuously performed.

As a result, a temperature difference of each substrate W transferred from the temperature adjustment chamber 5 to the second film formation processing chamber 3 is suppressed. In addition, in the second film formation processing chamber 3, the temperature of the stage 32 at the starting time of film formation can be stabilized. As a result, variations in the quality of the second film formed on the continuously processed substrate W can be suppressed.

While the film formation processing system 1 has been described hereinabove, the present disclosure is not limited to the above-described embodiments. Various modifications and improvements are possible within the scope of the present disclosure as stated in the claims.

According to one aspect of the present disclosure, a film formation processing system and a method for controlling the film formation processing system that suppress the impact of a temperature variation on film quality can be provided.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A film formation processing system, comprising:
a first film formation processing chamber configured to perform a first substrate processing on a substrate;
a second film formation processing chamber configured to perform a second substrate processing on the substrate;
a transfer chamber provided between the first film formation processing chamber and the second film formation processing chamber;
a temperature adjustment chamber provided in the transfer chamber and configured to perform a temperature adjustment processing of the substrate on which the first substrate processing has been performed before the second substrate processing is performed; and
a controller,
wherein the temperature adjustment chamber includes:
a first processing container;
a first stage provided inside the first processing container and configured to place the substrate on the first stage;
a first refrigerator configured to cool the first stage;
a radiation shield provided between the first processing container and the first stage; and
a first gas supply configured to supply a gas into the first processing container.

2. The film formation processing system of claim 1, wherein the controller is configured to perform an adjusting a temperature of the first stage of the temperature adjustment chamber, before processing the substrate, and
wherein the processing the substrate includes the first substrate processing performed in the first film formation processing chamber, the temperature adjustment processing performed in the temperature adjustment chamber, and the second substrate processing performed in the second film formation processing chamber.

3. The film formation processing system of claim 2, wherein the controller is configured to control the first gas supply to supply the gas into the first processing container, in the adjusting the temperature of the first stage of the temperature adjustment chamber.

4. The film formation processing system of claim 3, wherein the controller is configured to control a pressure inside the first processing container, thereby adjusting the temperature of the first stage, in the adjusting the temperature of the first stage of the temperature adjustment chamber.

5. The film formation processing system of claim 4, wherein the temperature adjustment chamber includes a pressure regulating valve configured to regulate the pressure inside the first processing container.

6. The film formation processing system of claim 5, wherein the gas supplied by the first gas supply is a noble gas.

7. The film formation processing system of claim 6, wherein the second film formation processing chamber includes:
a second processing container;
a second stage provided inside the second processing container and configured to place the substrate on the second stage;
a second refrigerator configured to cool the second stage;
a rotation mechanism configured to rotate the second stage; and
a lifting mechanism configured to switch between the second stage and the second refrigerator being separated from each other and the second stage and the second refrigerator being in contact with each other, and
wherein the controller is configured to perform adjusting a temperature of the second stage of the second film formation processing chamber, before the processing the substrate.

8. The film formation processing system of claim 7, wherein the controller is configured to control the lifting mechanism to switch between the second stage and the second refrigerator being separated from each other and the second stage and the second refrigerator being in contact with each other, thereby adjusting the temperature of the second stage, in the adjusting the temperature of the second stage of the second film formation processing chamber.

9. A method of controlling a film formation processing system including a first film formation processing chamber configured to perform a first substrate processing on a substrate, a second film formation processing chamber configured to perform a second substrate processing on the substrate, a transfer chamber provided between the first film formation processing chamber and the second film formation processing chamber, and a temperature adjustment chamber provided in the transfer chamber configured to perform a temperature adjustment processing of the substrate on which the first substrate processing has been performed before the second substrate processing is performed,
wherein the temperature adjustment chamber includes:
a first processing container;
a first stage provided inside the first processing container and configured to place the substrate on the first stage;
a first refrigerator configured to cool the first stage;
a radiation shield provided between the first processing container and the first stage; and
a first gas supply configured to supply a gas into the first processing container,
wherein the method comprises:
adjusting a temperature of the first stage of the temperature adjustment chamber; and
after the adjusting the temperature of the first stage, processing the substrate, and
wherein the processing the substrate includes the first substrate processing performed in the first film formation processing chamber, the temperature adjustment processing performed in the temperature adjustment chamber, and the second substrate processing performed in the second film formation processing chamber.

10. The method of claim 9, wherein the adjusting the temperature of the first stage of the temperature adjustment chamber is performed by supplying the gas into the first processing container by the first gas supply.

11. The method of claim 10, wherein the adjusting the temperature of the first stage of the temperature adjustment chamber is performed by controlling a pressure inside the first processing container.

12. The method of claim 11, wherein the second film formation processing chamber includes:
a second processing container;
a second stage provided inside the second processing container and configured to place the substrate on the second stage;
a second refrigerator configured to cool the second stage;
a rotation mechanism configured to rotate the second stage; and
a lifting mechanism configured to switch between the second stage and the second refrigerator being separated from each other and the second stage and the second refrigerator being in contact with each other, and
wherein the method further comprises:
adjusting a temperature of the second stage of the second film formation processing chamber, before the processing the substrate.

13. The method of claim 12, wherein the adjusting the temperature of the second stage of the second film formation processing chamber includes controlling the lifting mechanism to switch between the second stage and the second refrigerator being separated from each other and the second stage and the second refrigerator being in contact with each other.

14. The method of claim 9, wherein the second film formation processing chamber includes:
a second processing container;
a second stage provided inside the second processing container and configured to place the substrate on the second stage;
a second refrigerator configured to cool the second stage;
a rotation mechanism configured to rotate the second stage; and
a lifting mechanism configured to switch between the second stage and the second refrigerator being separated from each other and the second stage and the second refrigerator being in contact with each other, and
wherein the method further comprises:
adjusting a temperature of the second stage of the second film formation processing chamber, before the processing the substrate.
